(19) United States
(12) Patent Application Publication
(10) Pub. No.: US 2010/0084785 A1
(43) Pub. Date: Apr. 8, 2010

(54) METHOD FOR MANUFACTURING MASTER AND METHOD FOR MANUFACTURING OPTICAL DISC

(75) Inventors: Shin Masuhara, Tokyo (JP); Ariyoshi Nakaoki, Tokyo (JP); Takeshi Yamasaki, Kanagawa (JP); Tomomi Yukumoto, Chiba (JP)

Correspondence Address: ROBERT J. DEPKE;LEWIS T. STEADMAN, ROCKEY, DEPKE & LYONS, LLC, SUITE 5450 SEARS TOWER, CHICAGO, IL, 60606-6306, US

(73) Assignee: Sony Corporation, Tokyo (JP)

(21) Appl. No.: 12/557,747

(22) Filed: Sep. 11, 2009

(30) Foreign Application Priority Data
Oct. 2, 2008 (JP) 2008-257108

(51) Int. Cl. B29C 33/38; G03F 7/20

(52) U.S. Cl. 264/220; 430/296

(57) ABSTRACT

A method for manufacturing a master includes the steps of forming an inorganic resist layer on a master-forming substrate and forming, on a surface of the inorganic resist layer, a protective thin film containing a high-refractive-index material which has a refractive index n satisfying n≧NA of an exposure optical system and which is mixed in a light-transmitting material, performing near-field exposure with NA>1 on the protecting thin film using an exposure optical system, separating the protective thin film from an inorganic resist master subjected to the exposure, and forming a protrusion/depression pattern including exposed portions and unexposed portions by development of the inorganic resist master from which the protective thin film is separated.

### BACKGROUND OF THE INVENTION

1. Field of the Invention

The present invention relates to a method for manufacturing a master using an inorganic resist master and near-field exposure and a method for manufacturing an optical disc.

2. Description of the Related Art

At the start of a full-scale HD (High Definition) video age due to popularization of digital broadcasting, increases in recording density of optical discs are advanced from DVD (Digital Versatile Disc) which is the mainstream at present to Blu-ray Disc (registered trade name) or HD-DVD.

In a mastering step of optical discs, patterns such as pits and grooves are formed by lithography using laser exposure. However, the recording density has been increased mainly by contracting exposure spots.

When a laser beam at wavelength λ is condensed by an objective lens having numerical aperture (NA) during mastering, the exposure spot diameter φ is 1.22×(λ/NA). Since objective lenses with NA of 0.90 to 0.95 close to the theoretical limit value 1 have been used from the beginning of development of CD (Compact Disc), shortening of the wavelengths of recording laser light sources has mostly contributed to contraction of exposure spot diameters.

Although He—Cd laser at a wavelength of 442 nm or Kr+laser at a wavelength of 413 nm has been used in mastering of CD, use of Ar+laser at UV (Ultraviolet) wavelength of 351 nm has permitted manufacture of DVD. Further, DUV (Deep Ultraviolet) laser at a wavelength of 257 to 256 nm has been put into practical application, and thus recordable Blu-ray Disc (BD-RE) has been realized.

According to an approach apart from this, there has recently been technology of realizing dramatically higher-density recording by a simple process, which has been introduced into manufacture of reproduction-only Blu-ray Disc (BD-ROM). Although organic materials (photoresist) have been used for photosensitive layers during lithography, there has been found development in which with a specified inorganic material, unexposed portions are dissolved by alkali development, and resolution is significantly improved as compared with an organic resist process.

Japanese Unexamined Patent Application Publication No. 2003-315988 discloses a technique in which an inorganic material is used as a photosensitive material. Inorganic materials having a resist function are referred to as “inorganic resist” hereinafter.

FIG. 7 shows protrusion/depression shapes after exposure and development when an organic resist is used as a photosensitive material and when an inorganic resist is used as a photosensitive material.

In an organic resist process, recording is performed in a photon mode, and thus the minimum exposure pattern width is proportional to the exposure spot diameter and is substantially the same value as the spot diameter half-width value.

On the other hand, in an inorganic resist process, recording is performed in a heat mode, and thus when the threshold value of reaction temperature is sufficiently increased by design of a recording film structure, only a high-temperature portion near the center of an exposure spot contributes to recording, thereby permitting significant contraction of the effective recording spot diameter.

Therefore, pits of BD-ROM are not precisely formed using an organic resist even at a DUV wavelength, but when an inorganic resist is used, sufficient resolution is achieved even by a blue semiconductor laser light source.

A semiconductor laser is capable of high-speed modulation on the GHz order and capable of precisely controlling a pit shape by introducing write strategy used for signal recording on phase-change discs and magneto-optical discs, and thus the semiconductor laser is suitable for achieving good signal characteristics. The write strategy is a method for recording one pit by high-speed multipulses. In this case, a pattern shape is optimized by controlling the pulse width, pulse strength, pulse interval, and the like of pulses.

The above-described inorganic resist process is described in brief.

As shown in FIG. 8A, an inorganic resist master 100 basically includes a layer structure in which a heat storage control layer 100b and an inorganic resist layer 100c are deposited in order by sputtering on a support (master substrate 100a) composed of, for example, a Si wafer or quartz.

In the inorganic resist master 100, as shown in FIG. 8B, a beam (recording light) modulated according to a record signal is condensed on the master surface through an objective lens with a NA of about 0.9 to perform thermal recording. The inorganic resist master 100 is installed on a turn table of an exposure apparatus and rotated at a speed corresponding to a recording linear speed to move relatively to the objective lens at a predetermined feed pitch (track pitch) in a radial direction.

After exposure is completed, as shown in FIG. 8C, the inorganic resist master is developed with an organic alkali developer such as tetramethylammonium hydride (TMAH). As a result, protrusions/depressions corresponding to an exposure pattern are formed on the inorganic resist layer 100c. Namely, an exposed portion becomes a depressed portion corresponding to a pit shape or groove shape in the master.

### SUMMARY OF THE INVENTION

In such an inorganic resist process, the design of a recording film significantly influences resolution, but like in a related-art technique, the density may be further increased by reducing the diameter of a recording spot.

In order to reduce the diameter of a recording spot, besides a method of decreasing the wavelength of a recording light source, there is a method of realizing NA>1.0 by near field exposure in which a recording spot is applied with a solid immersion lens (SIL) brought close to a distance of several tens nm from a master.

With respect to application of a near field optical system to an optical disc, recording/reproduction by SIL having a NA close to 0 is reported at present (refer to Ariyoshi Nakaoki, Takao Kondo, Kimihiro Saito, Masataka Shinoda and Kazuo Fujiura, “High Numerical Aperture Hemisphere Solid Immersion Lens Made of KTaO₃ with Wide Thickness Tolerance”, Proceedings of SPIE Volume 6282, 62820 O-1˜62820 O-8). This method is capable of contracting a spot diameter to ½ for the maximum NA value (0.95) in a far-field optical system.

Since the minimum wavelength of a semiconductor laser light source capable of producing write strategy by high-speed modulation is currently 370 nm at most, a method of increasing NA by near-field exposure using a blue semiconductor laser is advantageous in view of mastering of ROM discs.

With respect to an organic resist process, an example has been reported, in which near-field exposure is applied to mastering of optical discs. For example, Japanese Unexamined Patent Application Publication No. 2001-56994 shows an optical system of a near-field exposure apparatus. An optical system of a near-field exposure apparatus is the same as a usual optical system until a recording laser beam is incident on an objective lens (SIL). However, a gap between the tip of SIL and a surface of a master is maintained at about 20 to 30 nm, and focusing is more precisely performed so as to avoid contact between both.

Therefore, as a focusing method specific to near-field exposure, it has been proposed that the intensity of interference light between light reflected from a master and light reflected from an emission surface of SIL is detected with PD, and a focus servo signal (gap servo signal) is produced using the phenomenon that the intensity of interference light changes with the gap between the master and SIL.

However, the set intensity of recording light varies according to resist sensitivity and target pattern dimensions, and a pulse width also varies depending on the shapes of drawn patterns such as grooves and pits. Therefore, the emission strength varies each time of mastering, and thus it is difficult to use recording light for determining the gap between the master and SIL from the intensity of interference light. Therefore, a focusing laser which emits at constant strength is separately provided.

If a near-field state is stably maintained by this method, a usual exposure process may be performed.

When the near-field exposure is introduced into an inorganic resist process, it may be expected to achieve the maximum recording density in optical recording using a laser as a light source.

With respect to the inorganic resist process, mastering of a ROM pattern of 100 GB on a disc having a diameter of 12 cm has been succeeded in a far-field recording optical system with a recording wavelength of 405 nm and a NA of 0.95 (refer to Shin Masuhara, Ariyoshi Nakaoki, Takashi Shimouma and Takeshi Yamasaki, “Real Ability of PTM Proved with the Near Field”, Proceedings of SPIE Volume 6282, 628214-1˜628214-8).

Therefore, when near-field exposure is introduced into the inorganic resist process, recording (exposure) of ROM of 400 GB is estimated to be possible with the same wavelength and a NA of 1.9.

In such a super high-density field, there is competition with electron beam lithography, but there are the advantages of simplicity of an exposure apparatus and reliability and practicability of the inorganic resist process having achievement of manufacture of reproduction-only Blu-ray discs (BD-ROM).

In addition, in application to micropattern processing other than optical discs, a line width L/S of 40 nm or less may be achieved, and thus the near-field exposure is promising.

However, as a result of actual attempt of near-field exposure for an inorganic resist master in expectation of the above-described effect, the problem described below occurred as long as tungsten oxide, which is most frequently used as a resist material, was used as a main material, thereby failing to perform normal focusing and achieve recording.

When a near-field exposure apparatus is used for an inorganic resist master, a surface of SIL is stained with gases evaporating from a resist surface even with a reproduction power of an objective lens output of as low as about 0.1 mW, thereby disturbing the gap servo signal. As a result, a focusing operation becomes unstable, resulting in contact between SIL and a master.

Further, even if this problem is resolved to permit pattern recording, a problem described below is expected to newly occur.

In the case of inorganic resist, a portion exposed in pattern recording protrudes by 20 to 30 nm. In a near-field state, the gap between SIL and a surface of a master is close to about 20 nm, and thus the gap is filled due to the protrusion of a pattern, causing the high possibility of contact.

In view of these problems, it has been difficult to introduce near-field exposure to the inorganic resist process. It is desirable to realize significantly high-density recording by combination of near-field exposure and an inorganic resist process.

A method for manufacturing a master according to an embodiment of the present invention includes the steps of forming an inorganic resist layer on a master-forming substrate and forming, on a surface of the inorganic resist layer, a protective thin film containing a high-refractive-index material which has a refractive index n satisfying n≧NA of an exposure optical system and which is mixed in a light-transmitting material, performing near-field exposure with NA>1 on the protecting thin film of the inorganic resist master using an exposure optical system, separating the protective thin film from the inorganic resist master subjected to the exposure, and forming a protrusion/depression pattern including exposed portions and unexposed portions by development of the inorganic resist master from which the protective thin film is separated.

The high-refractive-index material in the protective thin film is titanium oxide.

The protective thin film is formed by applying a constituent material of the protective thin film on a surface of the inorganic resist layer by spin coating and then curing.

The protective thin film is separated by immersion in a developer used for the development.

A method for manufacturing an optical disc according to an embodiment of the present invention includes the steps of forming a stamper form the inorganic resist master manufactured by the above-described method for manufacturing a master, and forming a disc substrate using the stamper and forming a predetermined layer structure on the disc substrate to produce an optical disc.

When an inorganic resist is applied to near-field recording, the present invention provides such an inorganic resist recording film structure that no gas is generated from a surface, and pattern protrusion during recording is suppressed to 10 nm or less at most.

That is, in lithography of a master, the protective thin film is previously formed on the surface of the inorganic resist layer and the protective thin film is separated after exposure, followed by development.

The exposure is performed in a state in which the inorganic resist layer is covered with the protective thin film, thereby avoiding the problem that when laser is applied directly to an inorganic resist, a surface of a solid immersion lens is stained due to volatilization of a resist material, thereby destabilizing control of the gap between the master and the lens.

Further, protrusion of the inorganic resist in an exposed portion is suppressed by the protective thin film, thereby avoiding the possibility that the gap between the master and the solid immersion lens is filled due to protrusion of several tens nm after recording of the inorganic resist, causing contact therebetween.

As a result, combination of an inorganic resist and near-field recording is realized, permitting higher-density recording.

According to the present invention, it may be possible to resolve the problem that a surface of a solid immersion lens close to a resist surface with a gap of only several tens nm is easily stained due to gas vaporization from the resist surface by heat of a condensed spot, and thus a gap servo signal is disturbed. Further, it may be possible to resolve the problem that the height of protrusion of the inorganic resist after exposure is equivalent to the gap length of several tens nm between the resist and the solid immersion lens, and a trouble of contact between the lens and the master occurs. As a result, a stable exposure operation may be carried out.

Therefore, it may be possible to realize combination of an inorganic resist process having predominantly higher resolution than that of an organic resist process and a near-field recording technique in which the diameter of a recording spot is decreased as NA of an objective lens increases, thereby realizing significantly high-density recording (exposure).

### BRIEF DESCRIPTION OF THE DRAWINGS

FIG. 1 is a drawing illustrating a near-field exposure apparatus used in an embodiment of the present invention;

FIGS. 2A and 2B drawings illustrating a mask of a near-field exposure apparatus and results of detection of the quantity of light according to an embodiment:

FIGS. 3A to 3I are drawings illustrating steps for manufacturing an optical disc according to an embodiment;

FIGS. 4A to 4D are drawings illustrating near-field exposure of an inorganic resist master according to an embodiment;

FIGS. 5A to 5D are drawings showing AFM observed images as experiment results according to an embodiment;

FIGS. 6A to 6D are drawings showing AFM observed images as a comparative example;

FIG. 7 is a drawing illustrating high-resolution characteristics of an inorganic resist; and

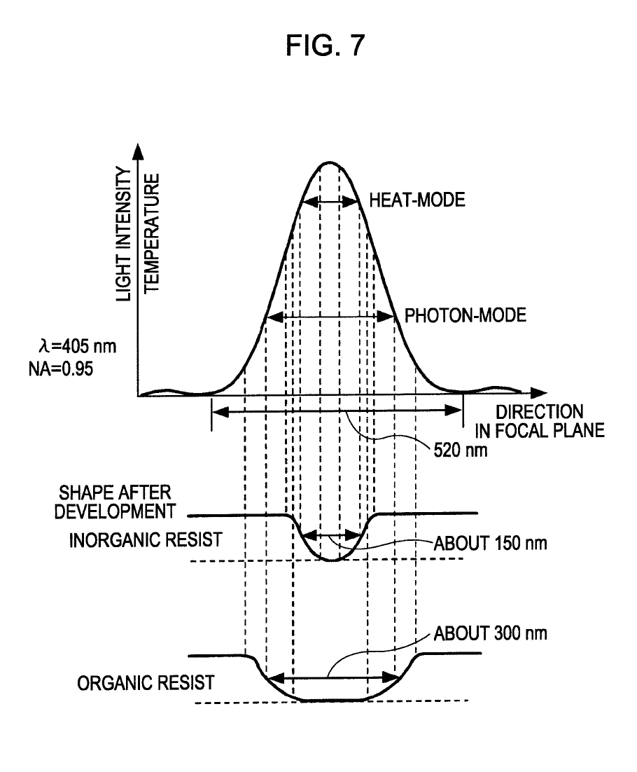

FIGS. 8A to 8C are drawings illustrating inorganic resist lithography.

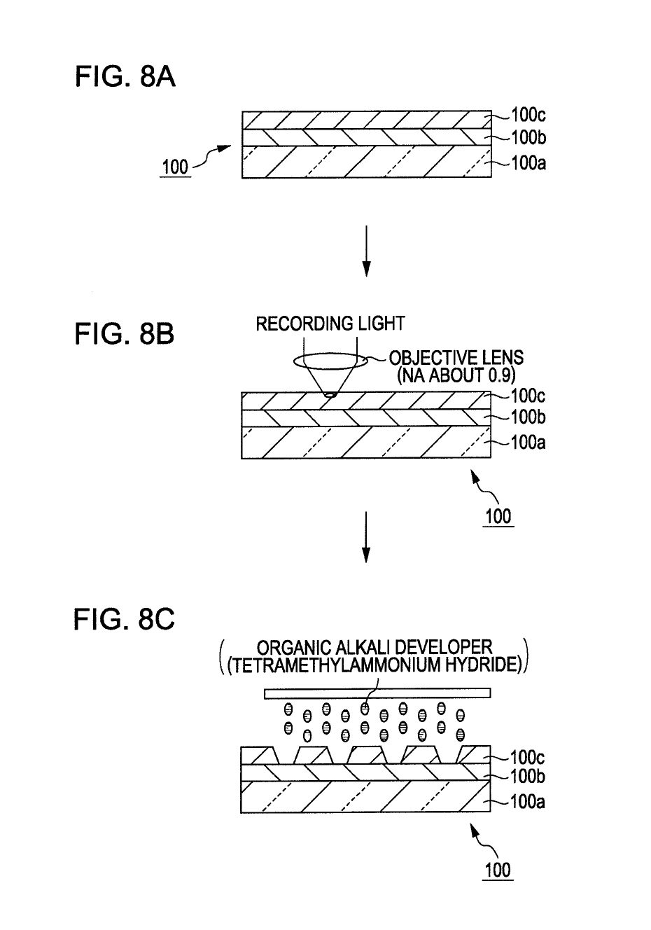

### DESCRIPTION OF THE PREFERRED EMBODIMENTS

An embodiment of the present invention is described in the following order.

1. Near-field exposure apparatus

2. Steps for manufacturing optical disc

3. Near-field exposure of inorganic resist master

4. Experimental example

5. Summary

### 1. Near-Field Exposure Apparatus

In an embodiment of the present invention, exposure is performed using a near-field exposure apparatus for a master (inorganic resist master) including an inorganic resist as a photosensitive material.

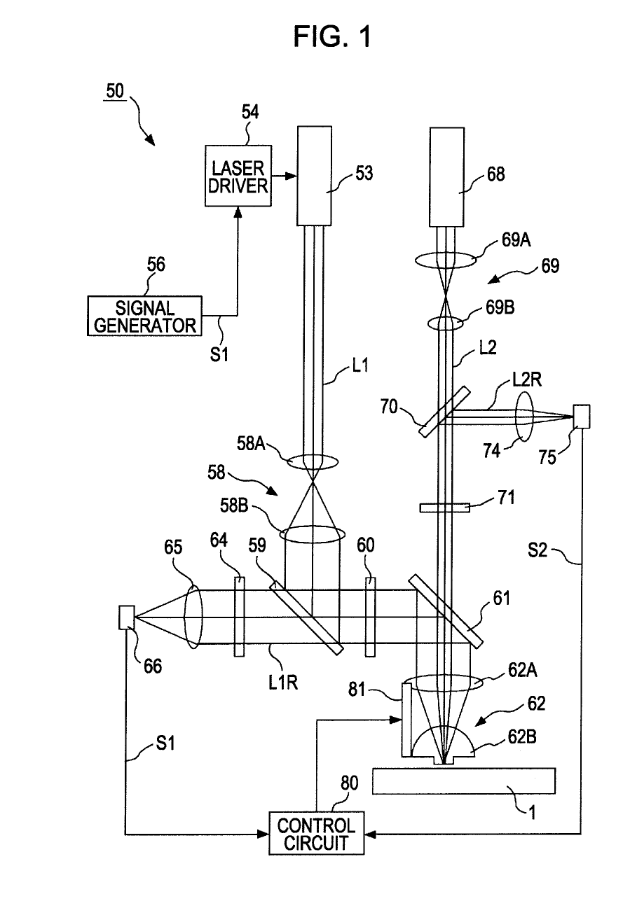

First, a near-field exposure apparatus is described with reference to FIGS. 1, 2A, 2B, and 3A to 3I.

FIG. 1 shows the configuration of a near-field exposure apparatus 50 used in a manufacturing process according to the embodiment.

In the near-field exposure apparatus 50, in a state in which an inorganic resist master 1 is rotated by a predetermined driving mechanism, a recording laser beam L1 is applied to the inorganic resist master 1 while the irradiation position is successively moved to the outer peripheral side of the inorganic resist master 1. As a result, a spiral track is formed as a pit train (or a groove) on the inorganic resist master 1.

In the near-field exposure apparatus 50, a laser light source 53 includes a semiconductor laser and emits recording laser beam L1 at a predetermined wavelength.

A signal generator 56 outputs a modulation signal S1 corresponding to a pit train to a laser driver 54. The laser driver 54 drives the laser light source (semiconductor laser) 53 on the basis of the modulation signal S1. As a result, the recording laser beam L1 on-off modulated on the basis of the modulation signal S1 is output from the laser light source 53.

Lenses 58A and 58B constitute a beam expander 58 and enlarge the diameter of the recording laser beam L1 to a predetermined beam diameter.

A polarizing beam splitter 59 reflects the recording laser beam L1 emitted from the beam expander 58 and transmits return light L1R of the recording laser beam L1 from the inorganic resist master 1 side to separate between the return light L1R and the recording laser beam L1.

A ¼ wavelength plate 60 gives a phase difference to the recording laser beam L1 emitted from the polarizing beam splitter 59 to convert the recording laser beam L1 into circularly polarized light. Similarly, the ¼ wavelength plate 60 gives a phase difference to the return light L1R from the inorganic resist master 1 side to emit the circularly polarized incident return light L1R as linearly polarized light with a polarization plane perpendicular to the recording laser beam L1 to the polarizing beam splitter 59.

A dichroic mirror 61 reflects the recording laser beam L1 emitted from the ¼ wavelength plate 60 toward the inorganic resist master 1 and emits the return light L1R coming from the inorganic resist master 1 side toward the ¼ wavelength plate 60.

Also, the dichroic mirror 61 transmits a focusing laser beam L2 at a wavelength different from that of the recording laser beam L1 toward the inorganic resist master 1 and transmits and emits interference light L2R due to the focusing laser beam L2 coming from the inorganic resist master 1 side.

An objective lens 62 includes a pair of lenses, i.e., a so-called rear lens 62A and front lens 62B. The recording laser beam L1 is converted to a convergent beam flux by the rear lens 62A and then condensed on an emission surface of the front lens 62B by the rear lens-side surface of the front lens 62B.

As a result, the front lens 62B of the objective lens 62 constitutes SIL (Solid Immersion Lens), and the numerical aperture is set to 1 or more as a whole so that the recording laser beam L1 is applied to the inorganic master 1 due to a near-field effect.

The front lens 62B is formed to have a circular projection at the center of the inorganic resist master-side surface so as to prevent contact with the inorganic resist master 1.

In the near-field exposure apparatus 50, a pit pattern is exposed on the inorganic resist master 1 by applying the recording laser beam 1 through the above-described route.

In addition, the return light L1R from the inorganic resist master 1 and the emission surface of the objective lens 62 is produced. The return light L1R travels reversely along the optical path of the recording laser beam L1, and is transmitted through the polarizing beam splitter 59 and separated from the recording laser beam L1.

A mask 64 is disposed on the optical path of the return light L1R transmitted through the polarizing beam splitter 59. Paraxial rays of the return light L1R are shielded so that only a component corresponding to the recording laser beam L1 incident on the emission surface of the objective lens 62 at an angle larger than the critical angle is selectively transmitted.

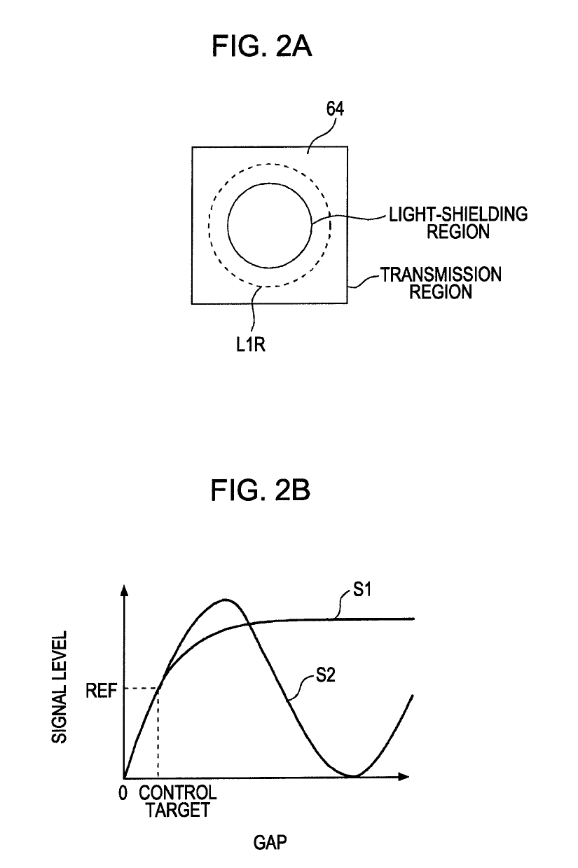

The mask 64 having the above function, as shown in FIG. 2A, includes a transparent parallel plate having a light-shielding region formed at the center thereof and having a diameter smaller than the beam diameter of the return light L1R. That is, in the return light L1R, a component incident on the emission surface of the objective lens 62 at an angle smaller than the critical angle is reflected by the emission surface of the objective lens 62 and the inorganic resist master 1, and the reflected lights interfere with each other. In the near-field exposure apparatus 50, therefore, the component of the interfering reflected light is removed by the mask 64 to treat the return light L1R.

A lens 65 condenses the return light L1R transmitted through the mask 64 on a light-receiving element 66 which outputs the light quantity detection result S1 of the return light L1R. Therefore, the mask 64 prevents variation of the light quantity detection result S1 due to interference of the reflected lights.

Therefore, the near-field exposure apparatus 50 is capable of detecting the quantity of the recording laser beam L1 completely reflected by the emission surface of the objective lens 62.

As shown in FIG. 2B, the light quantity detection result S1 detected as described above is maintained at a predetermined signal level when the objective lens 62 separates from the inorganic resist master 1 with a predetermined gap or more. On the other hand, when the objective lens 62 comes close to the inorganic resist master 1 with a predetermined gap or less, the signal level changes to correspond to the gap between the tip of the objective lens 62 and the inorganic resist master 1.

A laser light source 68 includes a He—Ne laser which emits the focusing laser beam L2 at a wavelength different from that of the recording laser beam L1 so that the inorganic resist master 1 is not exposed.

Lenses 69A and 69B constitute a beam expander 69 and reduce the diameter of the focusing laser beam L2 to a small beam diameter.

A polarizing beam splitter 70 transmits the light emitted from the beam expander 69 and reflects interference light L2R of the focusing laser beam L2 incident reversely along the optical path of the transmitted light to separate between the interference light L2R and the focusing laser beam L2.

A ¼ wavelength plate 71 gives a phase difference to the focusing laser beam L2 emitted from the polarizing beam splitter 70 to convert the focusing laser beam L2 into circularly polarized light and emit the polarized light to the dichroic mirror 61.

Similarly, the ¼ wavelength plate 70 gives a phase difference to the interference light L2R incident on the polarizing beam splitter 70 from the dichroic mirror 61 to emit the circularly polarized incident interference light L2R as linearly polarized light with a polarization plane perpendicular to the focusing laser beam L2 to the polarizing beam splitter 20.

In the near-field exposure apparatus 50, the focusing laser beam L2 having a smaller beam diameter at a wavelength different from that of the recording laser beam L1 is incident on the objective lens 62 together with the recording laser beam L1 and is applied to the inorganic resist master 1. The focusing laser beam L2 is incident by paraxial rays of the objective lens 62.

Therefore, the focusing laser beam L2 is reflected by the emission surface of the objective lens 62 and the surface of the inorganic resist master 1. Since the objective lens 62 and the inorganic resist master 1 are disposed close to each other so as to be put in near-field recording, the reflected lights interfere with each other. The interference light L2 of the reflected lights travels reversely along the optical path of the focusing laser beam L2, is incident on the polarizing beam splitter 70, and is reflected by the polarizing beam splitter 70 to be separated from the focusing laser beam L2.

A lens 74 condenses the interference light L2R reflected by the polarizing beam splitter 70 on a light-receiving element 75 which outputs the light quantity detection result S2.

As shown in FIG. 2B, in the light quantity detection result S2, a signal level changes in a sine-wave form at a period in which the gap between the tip of the objective lens 62 and the inorganic resist master 1 changes by ½ of the wavelength of the focusing laser beam L2.

A control circuit 80 controls focus of the objective lens 62 by driving an actuator 81 on the basis of the light quantity detection results S1 and S2.

Namely, when the start of exposure is indicated by an operator, the control circuit 80 moves the objective lens 62 to, for example, an inner peripheral region of the inorganic resist master 1 irrelevant to recording of a pit train on the inorganic resist master 1.

Further, the control circuit 80 drives a signal generator 56 to continuously apply the recording laser beam L1 to the inner peripheral region. In this state, the control circuit 80 drives the actuator 81 to gradually bring the objective lens 62 close to the inorganic resist master 1 and monitor the light quantity detection result S1 related to total reflection.

When a decrease of the signal level of the liquid quantity detection result S1 is started to detect approach of the objective lens 62 to the inorganic resist master 1 to the extent of exhibiting the near-field effect, and when it is decided from the light quantity detection result S1 related to whole refection that the objective lens 62 is brought close to the inorganic resist master 1 until the control target is substantially attained, the control circuit 80 starts focus control by a feedback loop on the basis of the light quantity detection result S2 of the interference light L2R.

Namely, in the focus control, the control circuit 80 drives the actuator 81 so that an error signal between a reference voltage REF corresponding to the control target and the light quantity detection result S2 of interference light becomes 0 level.

When the control circuit 80 starts the focus control on the basis of the light quantity detection result S2 of interference light L2R, the operation of the signal generator 56 is controlled to stop continuous application of the recording laser beam L1 and then move the objective lens 62 to the exposure start position. Further, the control circuit 80 starts modulation of the recording laser beam L1 by the signal generator 56 to start exposure of the inorganic resist master 1 from the exposure start position.

In the near-field exposure apparatus 50, the optical system is the same as a usual optical system until the recording laser beam L1 is incident on the objective lens 62. However, the gap between the tip of the objective lens 62 and the surface of the inorganic resist master 1 is maintained at about 20 to 30 nm, and focusing is more precisely performed so as to avoid contact between both.

Therefore, in the above-described configuration, the intensity of interference light of light reflected from the inorganic resist master 1 and light reflected from the emission surface of the objective lens 62 (SIL) is detected, and a focus servo signal (gap servo signal) is produced using the phenomenon that the intensity of interference light changes with the gap between the master and SIL.

### 2. Steps for Manufacturing Disc

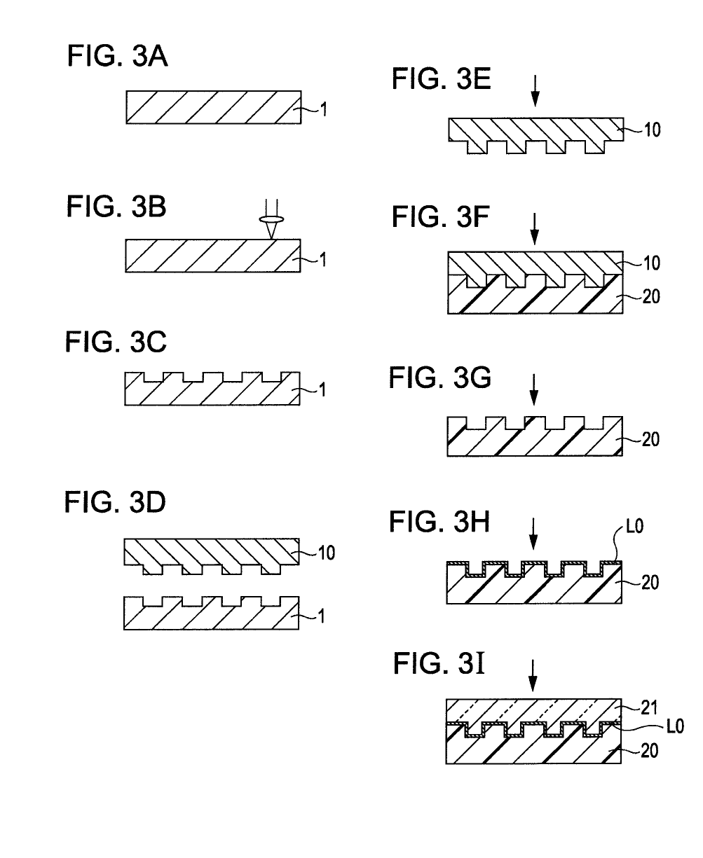

Then, the whole of the steps for manufacturing a disc according to the embodiment is described with reference to FIGS. 3A to 3I.

FIG. 3A shows the inorganic resist master 1.

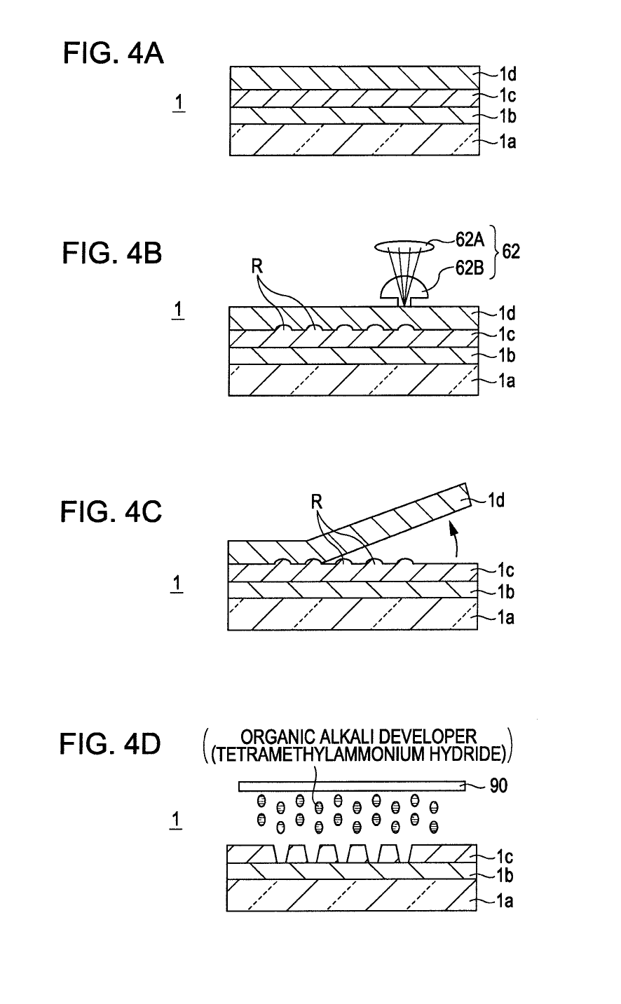

The structure of the inorganic resist master 1 is described later with reference to FIGS. 4A to 4D.

The inorganic resist master 1 is selectively exposed to light according to a pit train as a signal pattern using the near-field exposure apparatus 50 (FIG. 3B).

Then, the resist layer is developed (etched) to produce the inorganic resist master 1 on which a predetermined protrusion/depression pattern (pit train) is formed (FIG. 3C).

These are steps for manufacturing a master.

Then, steps for producing a stamper are performed. That is, a metal nickel film is deposited by plating on the protrusion/depression pattern of the inorganic resist master 1 formed as described above, and then the metal nickel film is separated from the inorganic resist master 1 and subjected to predetermined processing to form a stamper 10 to which the protrusion/depression pattern of the inorganic resist master 1 is transferred (FIGS. 3D and 3E).

Then, optical discs are mass-produced using the stamper.

First, a resin-made disc substrate 20 composed of polycarbonate, which is a thermoplastic resin, is molded by injection molding using the stamper 10 (FIG. 3F). The stamper 10 is separated to produce the disc substrate 20 (FIG. 3G).

Then, a reflective film composed of an Ag alloy is formed on the production/depression surface of the resin-made disc substrate 20 to form a recording layer L0 (FIG. 3H).

Further, a light-transmitting layer (cover layer) 21 is formed on the recording layer L0 (FIG. 3I).

As a result, an optical disc is completed. That is, a reproduction-only disc on which a pit train is formed is manufactured.

In addition, a hard coat layer may be formed on the surface of the light-transmitting layer 21.

### 3. Near-Field Exposure of Inorganic Resist Master

The steps for manufacturing an optical disc according to the embodiment have the characteristics of the layer structure of the inorganic resist master 1 and the steps up to development of the inorganic resist master 1.

This character is described below.

As described above, when the near-field exposure apparatus 50 is used for the inorganic resist master 1, a surface of SIL is stained with gases evaporating from a resist surface, thereby disturbing the gap servo signal. As a result, a focusing operation becomes unstable, resulting in contact between SIL and a master.

In addition, in the case of inorganic resist, a portion exposed during pattern recording protrudes by 20 to 30 nm. In a near-field state, the gap between SIL and a surface of the master is close to about 20 nm, and thus the gap is filled due to the protrusion of a pattern, causing the high probability of contact.

In the embodiment, therefore, when an inorganic resist is applied to near-field recording, the inorganic resist master 1 has a recording film structure which generates no gas from the surface and which suppresses pattern protrusion to 10 nm or less at most during recording.

Namely, a protective thin film having a recording film gas sealing effect and a recording film protrusion suppressing effect is formed on the surface of the inorganic resist film. After completion of recording, the thin film is removed by any method such as a mechanical separating method, a chemical method using a solvent, or the like, and then development is performed.

FIG. 4A shows the structure of the inorganic resist master 1 of the embodiment.

The inorganic resist master 1 includes a heat storage control layer 1b and an inorganic resist layer 1c which are deposited by sputtering on a master substrate (support) 1a composed of a Si wafer or quartz, and a surface coat layer 1d formed as a protective thin film on the surface of the inorganic resist layer 1c.

The heat storage control layer 1b is used for heating the inorganic resist without escaping the heat applied from an exposure spot to the master substrate 1a. Although an increase in the thickness increases resist sensitivity, an excessively high heat storage effect degrades resolution due to excessive heat diffusion in a planar direction. Therefore, it is important to select a material and thickness so that the resist sensitivity and resolution are balanced. In fact, amorphous silicon (a-Si), SiO₂, or SiN is used in a thickness of about 20 to 100 nm.

As an inorganic resist material for the inorganic resist layer 1c, an incomplete oxide of a transition metal is used. Specific examples of the transition metal include Ti, V, Cr, Mn, Fe, Nb, Cu, Ni, Co, Mo, Ta, W, Zr, Ru, Ag, and the like.

As the surface coat layer 1d, specifically, a light-transmitting material which is used as a surface coat for near-field recording/reproduction disc and which contains a high-refractive-index material (e.g., TiO₂) is suitable.

The surface coat material is uniformly applied to a thickness of about 0.5 μm to several μm by spin coating, and even if the inorganic resist protrudes by several tens nm after recording, the surface coat material absorbs the protrusion because of its low hardness and prevents surface protrusion. In addition, when the refractive index n of the high-refractive-index material satisfies n≧NA (>1) of SIL, near-field recording/reproduction is possible without degrading NA of SIL.

The inorganic resist master 1 on which the surface coat layer 1d is formed is exposed to light using the near-field exposure apparatus 50.

FIG. 4B shows the exposure.

In this case, the surface coat layer 1d exhibits the effect of sealing gases evaporating from the inorganic resist layer 1c. Therefore, a stable focusing operation is realized without staining the SIL surface with the evaporating gases.

The inorganic resist layer 1c protrudes by several tens nm in an exposed portion. This is due to cubical expansion which is caused by phase change of the inorganic resist from an amorphous state to a crystalline state in an exposed portion.

However, in this case, protrusion is suppressed by the surface coat layer 1d, and thus a surface facing the objective lens 62 is little affected.

After exposure, as shown in FIG. 4C, the surface coat layer 1d is separated from the inorganic resist master 1.

Then, as shown in FIG. 4D, development is performed for the inorganic resist master after the surface coat layer 1d is separated therefrom using an organic alkali developer such as tetramethylammonium hydride (TMAH). As a result, protrusions/depressions corresponding to an exposure pattern (pit train) are formed on the inorganic resist layer 1c. Namely, exposed portions become depressions corresponding to a pit shape or groove shape on a master.

In the lithography process for the inorganic resist master, the surface coat is formed after the inorganic resist is deposited, and the surface coat is removed after exposure. Therefore, near-field exposure of an inorganic resist is enabled with significantly high resolution as compared with an organic resist, thereby permitting higher-density recording.

### 4. Experimental Example

As a result of actual near-field recording on the inorganic resist master 1 by the above-described method, high-density recording with substantially utilizing NA of a solid immersion lens (SIL) was succeeded.

An experimental example of the process is described in detail below.

### Process 1: Master Manufacturing Step

Although a usual resist master includes a flat silicon or quartz wafer, an inorganic resist layer was deposited on a plastic substrate on which a tracking pregroove was formed for convenience of use of a near-field recording/reproduction apparatus for discs in an experiment.

The pregroove had a track pitch of 190 nm and a depth of about 20 nm.

A layer structure formed on the plastic substrate included an a-Si (amorphous silicon) heat storage control layer 1b having a thickness of 80 nm and a tungsten oxide inorganic resist layer 1c having a thickness of 40 nm.

### Process 2: Surface Coat Forming Step

A surface coat layer 1d was formed to a thickness of 1 μm on the surface of the inorganic resist layer of the substrate subjected to deposition in process 1.

Specifically, the surface coat layer 1d was composed of an acrylic hard coat agent (manufactured by JSR Corporation, trade name “DeSolite”) containing TiO₂ fine particles with a refractive index n of 2.5, which was diluted with methyl isobutyl ketone and isopropyl alcohol.

The surface coat layer 1d was fixed by the process of applying the diluted solution on the substrate by spin coating and then curing with ultraviolet rays.

### Process 3: Near-Field Exposure Step

A pit pattern of an optical disc was exposed on the inorganic resist substrate by a recording optical system including a semiconductor laser light source with a wavelength λ of 405 nm and SIL with a NA of 1.7.

A recording signal was RLL (1-7) pp signal used for BD-ROM (reproduction-only Blue-ray disc) (CLk=66 MHz).

In the exposure, the recording linear density (BD-ROM; 25 GB ratio), the minimum pit length, and the recording linear speed were the following four types.

(1) Sample 1; linear density=BD-ROM×2.00, minimum pit length 2T=75 nm, recording linear speed v=2.46 m/s

(2) Sample 2; linear density=BD-ROM×2.50, minimum pit length 2T=60 nm, recording linear speed v=1.98 m/s

(3) Sample 3; linear density=BD-ROM×2.73, minimum pit length 2T=55 nm, recording linear speed v=1.804 m/s

(4) Sample 4; linear density=BD-ROM×3.00, minimum pit length 2T=50 nm, recording linear speed v=1.65 m/s

The recording conditions, such as write strategy, recording power (Peak Power, Bias Power), etc., were the same in all samples. The peak power was 8.0 mW, and the bias power was 2.0 mW.

The presence of the surface coat layer 1d prevented destabilization of focusing during recording/reproduction and the occurrence of contact with SIL due to resist protrusion after recording, thereby realizing stable exposure.

### Process 4: Surface Coat Separating Step

After the exposure, the surface coat layer 1d formed in process 2 was removed for development.

Since the surface coat material had weak adhesive force to the inorganic resist surface, the surface coat layer was easily separated with the hand, starting from a flaw formed in the periphery of the disc with a cutter.

It was also confirmed that the surface coat layer was completely separated from the disc substrate within several minutes due to swelling of the coat film when immersed in an alkali developer.

This method is more practical because it may be performed in the same step as development.

### Process 5: Development Step

Like in a usual inorganic resist development step, the substrate subjected to exposure was developed by immersion for 12 minutes in a commercial organic alkali developer TMAH-2.38% solution (manufactured by Tokyo Ohka Kogyo Co., Ltd.; trade name “NMD-3”).

The results were as follows.

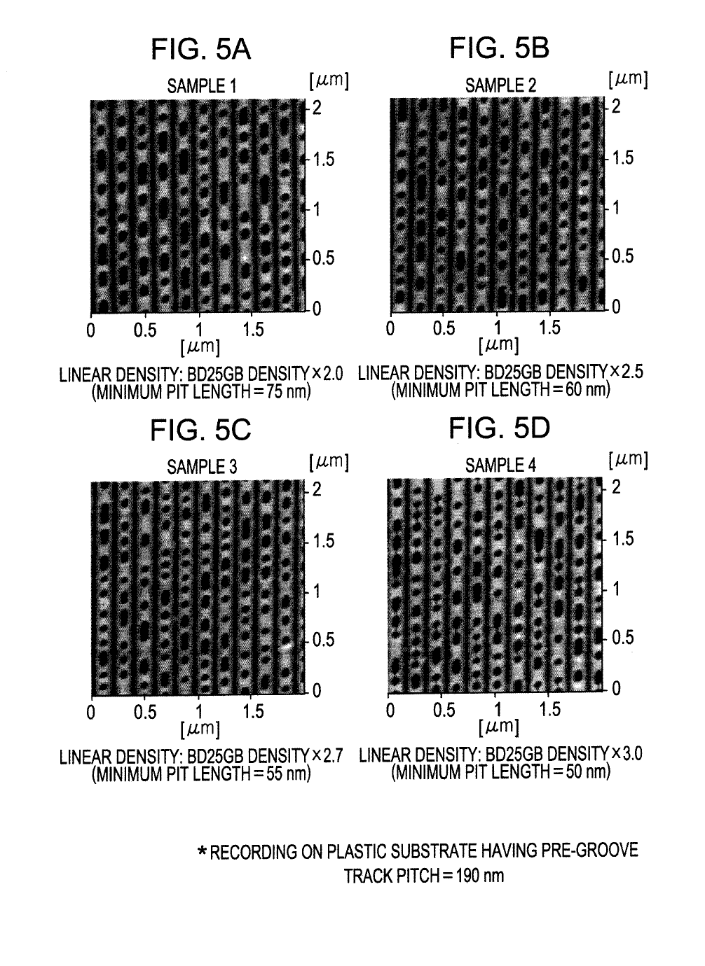

FIGS. 5A, 5B, 5C, and 5D show AFM observed images of Samples 1 to 4 formed through the above-described steps.

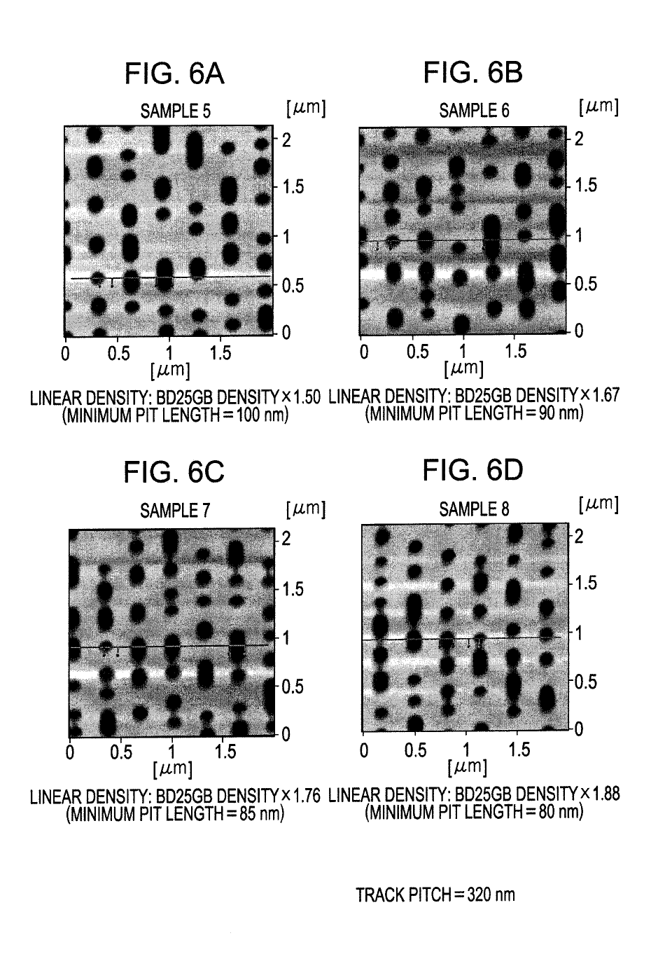

In the samples up to Sample 3 (linear density=BD-ROM×2 73) shown in FIG. 6C, the pits formed are clearly separated.

In Sample 4 (linear density=BD-ROM×3.00) shown in FIG. 5D, adjacent pits are connected in a minimum land portion with length 2T. Although it is expected that the pits are completely separated by adjusting the recording power, it is found that the recording resolution in the linear speed direction is close to the limit.

On the other hand, as a comparison, the recording resolution limit of recording in a far-field optical system is described, the far-field optical system including a semiconductor laser light source with a wavelength λ of 405 nm and an objective lens with a NA of 0.95.

FIGS. 6A, 6B, 6C, and 6D show AFM observed images of Samples 5 to 8 on each of which a pit train of the same recording signal RLL(1-7)pp signal was recorded.

Although the signal was recorded on a usual silicon wafer master without a pregroove, the resist structure was the same as in Samples 1 to 4, thereby permitting comparison of the recording optical system. The track pitch was 0.32 μm.

(1) Sample 5; linear density=BD-ROM×1.50, minimum pit length 2T=100 nm, recording linear speed v=3.28 m/s

(2) Sample 6; linear density=BD-ROM×1.67, minimum pit length 2T=90 nm, recording linear speed v=2.95 m/s

(3) Sample 7; linear density=BD-ROM×1.76, minimum pit length 2T=85 nm, recording linear speed v=2.79 m/s

(4) Sample 8; linear density=BD-ROM×1.88, minimum pit length 2T=80 nm, recording linear speed v=2.62 m/s

As seen from Sample 6 of FIG. 6B, pits are difficult to completely separate in the recording linear speed direction with the minimum pit length of 90 nm as a density. Although, in the near-field recording system in which NA=1.7, the limit of NA recording resolution was 2T=50 nm, the value is substantially proportional to NA (i.e., spot diameter) of the recording resolution limit (2T=90 nm) with NA of 0.95.

That is, in this experiment, the effect of near-field recording appears as an expected value in terms of NA. This suggests that the process according to the embodiment is effective.

Although the layers were deposited on the plastic substrate with a pregroove for convenience of experiment, of course, recording may be made on a flat master surface as long as a dedicated exposure apparatus having a near-field optical system is used, and a flat master surface is used in actual mastering.

Application is not limited to manufacture of an optical disc master, and other possible application is a usual micro processing apparatus in which, for example, an X-Y drawing stage is introduced.

In addition, the high-refractive-index material in the surface coat layer 1d is not limited to TiO₂ fine particles, and any material may be used as long as it has a refractive index higher than NA of SIL.

However, the light-transmitting material in which the high-refractive-index material is mixed is not much changed for the material used.

Even when another high-refractive-index material is used, a form which permits dilution with an alcohol and spin coating is used. Therefore, the above-described method for forming the surface coat and separating it is considered to have generality.

The material of the surface coat layer 1d is further described.

The performance as a light-transmitting material is improved as the content of high-refractive-index fine particles decreases and the particle diameter decreases. This is due to light scattering caused by a difference in refractive index between the high-refractive-index material and the light-transmitting material.

The average refractive index nc of the surface coat layer 1d is as follows:

nc=√{(X·(n1)²+(1−X)·(n2)^{2}} Equation (1)

wherein n1 is the refractive index of the high-refractive-index material, X is the volume filling rate of the high-refractive-index material, and n2 is the refractive index of the light-transmitting material.

Namely, as the refractive index of the high-refractive-index material increases, the content thereof is suppressed to a low value.

As a material which has a high refractive index and which may be formed in fine particles (particle diameter: about 5 nm), a metal oxide containing at least one selected from the group including Zr, Nb, Ti, Sn, Ta, Ca, and Zn is preferred. In particular, TiO₂ is considered to be suitable.

As inorganic oxide fine particles, oxide fine particles of indium oxide, zirconium oxide, titanium oxide, tin oxide, tantalum oxide, or the like, which has no absorption in the visible light wavelength region, are used. In particular, titanium oxide fine particles are considered as a preferred high-refractive-index material because they have the highest refractive index and are chemically stable.

The refractive index n1 of the high-refractive-index material has the following definition.

The minimum value of the average refractive index nc is determined by NA of the objective lens (when NA=nc).

The equation 1 is changed as follows:

n1²={(NA)²−(1−X)·(n2)²}/X Equation (2)

If there is a demand for controlling the volume filling rate X of the high-refractive-index material to 30% or less, the minimum value of n1 may be defined by the equation 2.

For example, when X=0.3, n1=2.5, and n2=1.55, nc is calculated at 1.89 which is larger than NA (=1.7).

In addition, when nc is controlled to 1.7, n1 is 2.00.

### 5. Summary

As described above, in the embodiment, when a micro pattern such as pits or groove is formed on the inorganic resist master 1 by lithography, the process is as follows. The surface coat layer 1d (protective thin film) containing high-refractive-index material fine particles is formed on the surface of the inorganic resist master 1 by spin coating.

Then, near-field exposure of a pattern on the inorganic resist master 1 is performed using a solid immersion lens. Next, the surface coat layer 1d is removed, and finally development is performed.

The presence of the surface coat layer 1d resolves the problem of near-field recording on an inorganic resist.

That is, there is the problem that the surface of a solid immersion lens adjacent to a resist surface at a gap of several tens nm is easily stained with gases evaporating from the resist surface by the heat of a condensed spot, thereby disturbing the gap servo signal. This problem is resolved by the gas sealing effect of the surface coat layer 1d.

There is also the problem that the protrusion height of the inorganic resist after exposure is substantially the same as the gap length of several tens nm between the resist and the solid immersion lens, thereby causing a trouble of contact between the lens and the master. This problem is resolved by the protrusion suppressing function of the surface coat layer 1d, permitting a stable exposure operation.

Therefore, combination of the inorganic resist process which exhibits significantly higher resolution than the organic resist process and the near-field recording technique in which the diameter of a recording spot is reduced with increase in NA of an objective lens is realized, and thus a significantly higher density is realized.

Although, in the embodiment, description is made of an example in which the present invention is applied to manufacture of Blu-ray disc, of course, the application is not limited to manufacture of Blu-ray disc. The present invention may be applied to manufacture of optical discs in which a higher density has been realized.

In addition, the present invention may be applied to pits or grooves of a high-recording density optical disc master and the formation of other patterns for micro processing in which equivalent dimensions are desired.

The present application contains subject matter related to that disclosed in Japanese Priority Patent Application JP 2008-257108 filed in the Japan Patent Office on Oct. 2, 2008, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A method for manufacturing a master comprising the steps of:
forming an inorganic resist layer on a master-forming substrate and forming, on a surface of the inorganic resist layer, a protective thin film containing a high-refractive-index material which has a refractive index n satisfying n≧NA of an exposure optical system and which is mixed in a light-transmitting material to form an inorganic resist master;
performing near-field exposure with NA>1 on the inorganic resist mater from above the protecting thin film using the exposure optical system;
separating the protective thin film from the inorganic resist master subjected to the exposure; and
forming a protrusion/depression pattern including exposed portions and unexposed portions by development of the inorganic resist master from which the protective thin film is separated.

2. The method for manufacturing a master according to claim 1, wherein the high-refractive-index material in the protective thin film is titanium oxide.

3. The method for manufacturing a master according to claim 1, wherein the protective thin film is formed by applying a constituent material of the protective thin film on the surface of the inorganic resist layer by spin coating and then curing.

4. The method for manufacturing a master according to claim 1, wherein the protective thin film is separated by immersion in a developer used for the development.

5. A method for manufacturing an optical disc comprising the steps of:
forming an inorganic resist layer on a master-forming substrate and forming, on a surface of the inorganic resist layer, a protective thin film containing a high-refractive-index material which has a refractive index n satisfying n≧NA of an exposure optical system and which is mixed in a light-transmitting material to form an inorganic resist master;
performing near-field exposure with NA>1 on the inorganic resist mater from above the protecting thin film using the exposure optical system;
separating the protective thin film from the inorganic resist master subjected to the exposure;
forming a protrusion/depression pattern including exposed portions and unexposed portions by development of the inorganic resist master from which the protective thin film is separated;
forming a stamper from the inorganic resist master subjected to the development; and
forming a disc substrate using the stamper and forming a predetermined layer structure on the disc substrate to produce an optical disc.
